(19) United States
(12) Patent Application Publication
(10) Pub. No.: US 2024/0318295 A1
(43) Pub. Date: Sep. 26, 2024

(54) APPARATUS FOR MANUFACTURING DISPLAY DEVICE, METHOD OF MANUFACTURING DISPLAY DEVICE, AND MASK ASSEMBLY

(71) Applicant: Samsung Display Co., Ltd., Yongin-si (KR)

(72) Inventors: Jeongkuk Kim, Yongin-si (KR); Seungyong Song, Yongin-si (KR); Duckjung Lee, Yongin-si (KR); Wonje Cho, Yongin-si (KR)

(73) Assignee: Samsung Display Co., Ltd., Yongin-si (KR)

(21) Appl. No.: 18/479,163

(22) Filed: Oct. 2, 2023

(30) Foreign Application Priority Data
Mar. 24, 2023 (KR) 10-2023-0039074
Apr. 21, 2023 (KR) 10-2023-0052820

(51) Int. Cl. C23C 14/04; H10K 59/12; H10K 71/16

(52) U.S. Cl. CPC C23C 14/042; H10K 59/1201; H10K 71/166; H10K 71/164

(57) ABSTRACT

An apparatus for manufacturing a display device includes a chamber, a mask assembly disposed inside the chamber to face a display substrate, and a deposition source unit that is disposed inside the chamber to face the mask assembly, supplies a deposition material, and deposits the deposition material on the display substrate by passing through the mask assembly, wherein the mask assembly includes a first mask layer including a first mask opening, and a second mask layer disposed on the first mask layer and including a second mask opening overlapping the first mask opening, and the second mask layer includes a first inorganic layer, a first organic layer disposed on the first inorganic layer, and a second inorganic layer disposed on the first organic layer.

### CROSS-REFERENCE TO RELATED APPLICATION(S)

This application claims priority under 35 U.S.C. § 119 to Korean Patent Application No. 10-2023-0039074, filed on Mar. 24, 2023, and Korean Patent Application No. 10-2023-0052820, filed on Apr. 21, 2023, in the Korean Intellectual Property Office, the entire contents of which are incorporated herein by reference herein.

### BACKGROUND

### 1. Technical Field

One or more embodiments relate to an apparatus and a method, and more particularly, to an apparatus for manufacturing a display device, a method of manufacturing a display device, and a mask assembly.

### 2. Description of the Related Art

A display device visually displays data. The display device may provide an image by using light-emitting diodes. Recently, display devices have been diversified in usage. Accordingly, various designs of the display devices have been attempted to improve the quality of the display devices.

### SUMMARY

One or more embodiments include a mask assembly capable of performing readily thickness adjustment, improving durability, and reducing (or minimizing) a clogging phenomenon of an opening through which a deposition material passes.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, an apparatus for manufacturing a display device may include a chamber, a mask assembly disposed inside the chamber to face a display substrate, and a deposition source unit that is disposed inside the chamber to face the mask assembly and supplies a deposition material, and deposits the deposition material on the display substrate by passing through the mask assembly, wherein the mask assembly may include a first mask layer including a first mask opening, and a second mask layer disposed on the first mask layer and including a second mask opening overlapping the first mask opening, wherein the second mask layer may include a first inorganic layer, a first organic layer disposed on the first inorganic layer, and a second inorganic layer disposed on the first organic layer.

In an embodiment, the second mask opening may include a first inorganic opening disposed in the first inorganic layer, a first organic opening disposed in the first organic layer, and a second inorganic opening disposed in the second inorganic layer.

In an embodiment, a width of the first organic opening may be greater than a width of the second inorganic opening in a cross-sectional view.

In an embodiment, a width of the first inorganic opening and the width of the second inorganic opening may be same as each other in a cross-sectional view.

In an embodiment, a width of the first inorganic opening, a width of the first organic opening, and a width of the second inorganic opening may be same as each other in a cross-sectional view.

In an embodiment, a thickness of the first organic layer may be greater than a thickness of the first inorganic layer and a thickness of the second inorganic layer in a cross-sectional view.

In an embodiment, the first mask layer may include a silicon material.

In an embodiment, the second mask layer may further include a second organic layer disposed on the second inorganic layer, and a third inorganic layer disposed on the second organic layer.

According to one or more embodiments, a method of manufacturing a display device may include disposing a display substrate inside a chamber, disposing a mask assembly inside the chamber, and supplying a deposition material toward the mask assembly from a deposition source unit, wherein the disposing of the mask assembly may include disposing a second mask layer on a first mask layer, forming a first mask opening in the first mask layer, and forming a second mask opening in the second mask layer, wherein the disposing of the second mask layer may include disposing a first inorganic layer on the first mask layer, disposing a first organic layer on the first inorganic layer, and disposing a second inorganic layer on the first organic layer.

In an embodiment, the forming of the second mask opening may include forming a first inorganic opening in the first inorganic layer, forming a first organic opening in the first organic layer, and forming a second inorganic opening in the second inorganic layer.

In an embodiment, the forming of the second inorganic opening may include disposing, on the second inorganic layer, a first photoresist layer in which a first photo-opening is disposed, etching a portion of the second inorganic layer that overlaps the first photo-opening, and removing the first photoresist layer.

In an embodiment, the forming of the first organic opening may include etching a portion of the first organic layer that overlaps the second inorganic opening.

In an embodiment, a width of the first organic opening may be greater than a width of the second inorganic opening in a cross-sectional view.

In an embodiment, the forming of the first inorganic opening may include etching a portion of the first inorganic layer that overlaps the second inorganic opening.

In an embodiment, a width of the first inorganic opening and a width of the second inorganic opening may be same as each other in a cross-sectional view.

According to one or more embodiments, a mask assembly may include a first mask layer including a first mask opening, and a second mask layer disposed on the first mask layer and including a second mask opening overlapping the first mask opening, wherein the second mask layer may include a first inorganic layer, a first organic layer disposed on the first inorganic layer, and a second inorganic layer disposed on the first organic layer.

In an embodiment, the second mask opening may include a first inorganic opening disposed in the first inorganic layer, a first organic opening disposed in the first organic layer, and a second inorganic opening disposed in the second inorganic layer.

In an embodiment, a width of the first organic opening may be greater than a width of the second inorganic opening in a cross-sectional view.

In an embodiment, a thickness of the first organic layer may be greater than a thickness of the first inorganic layer and a thickness of the second inorganic layer in a cross-sectional view.

In an embodiment, the first mask layer may include a silicon material.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display device according to an embodiment;

FIG. 2 is a schematic cross-sectional view of a mask assembly according to an embodiment;

FIG. 3 is a schematic plan view of a portion of a second mask layer according to an embodiment;

FIGS. 4 to 11 are cross-sectional views for describing a method of manufacturing a display device according to an embodiment;

FIG. 12 is a schematic cross-sectional view of a mask assembly according to another embodiment;

FIG. 13 is a schematic cross-sectional view of a mask assembly according to another embodiment;

FIG. 14 is a schematic perspective view of a display device according to an embodiment;

FIG. 15 is a schematic cross-sectional view of a display device according to an embodiment;

FIG. 16 is a schematic plan view of a display panel according to an embodiment;

FIG. 17 is a schematic diagram of an equivalent circuit of a pixel included in a display device according to an embodiment; and

FIG. 18 is a schematic cross-sectional view of a display device according to an embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system, such as the x, y, and z axes, and may be interpreted in a broader sense. For example, the x-axis, the y-axis, and the z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

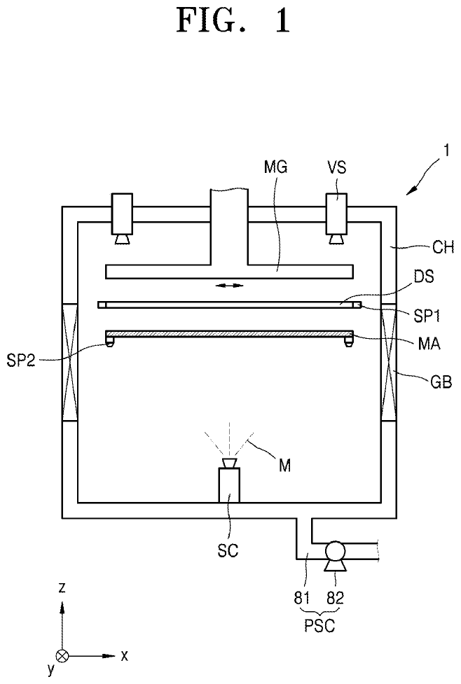

FIG. 1 is a schematic cross-sectional view of an apparatus for manufacturing a display device according to an embodiment.

An apparatus 1 for manufacturing a display device may include a chamber CH, a first support portion SP1, a second support portion SP2, a mask assembly MA, a deposition source unit SC, a magnetic force unit MG, a vision unit VS, and a pressure adjusting unit PSC.

The chamber CH may have a space therein, and a display substrate DS and the mask assembly MA may be accommodated in the space. For example, a portion of the chamber CH may be formed to be opened, and a gate valve GB may be installed on the open portion (e.g., entrance, door, or opening and closing parts) of the chamber CH. For example, the open portion of the chamber CH may be opened or closed according to an operation of the gate valve GB.

For example, the display substrate DS may include a substrate 100 and at least one of an organic layer, an inorganic layer, and a metal layer, which are deposited on the substrate 100, as described below, in a process of manufacturing a display device. In another example, the display substrate DS may be a substrate 100 on which any one of an organic layer, an inorganic layer, and a metal layer has not yet been deposited.

The first support portion SP1 may support the display substrate DS. For example, the first support portion SP1 may have a plate shape fixed inside the chamber CH. In another example, the first support portion SP1 may also have a shuttle shape such that the display substrate DS may be seated on the first support portion SP1 and may perform a linear movement in the chamber CH. In another example, the first support portion SP1 may also include an electrostatic chuck or an adhesive chuck, which is fixed to the chamber CH or arranged in the chamber CH to be movable in the chamber CH.

The second support portion SP2 may support the mask assembly MA. For example, the second support portion SP2 may be arranged in the chamber CH. The second support portion SP2 may finely adjust the position of the mask assembly MA. For example, the second support portion SP2 may include a separate driver or an alignment unit to move the mask assembly MA in a different direction from the moving direction of the second support portion SP2.

In another example, the second support portion SP2 may also have a shuttle shape. For example, the second support portion SP2 may include the mask assembly MA seated thereon and may transfer the mask assembly MA. For example, the second support portion SP2 may move to the outside of the chamber CH and enter the chamber CH from the outside of the chamber CH after the mask assembly MA is seated on the second support portion SP2.

For example, the first support portion SP1 may be integral with the second support portion SP2. For example, the first support portion SP1 and the second support portion SP2 may include a movable shuttle. For example, the first support portion SP1 and the second support portion SP2 include a structure that fixes the mask assembly MA and the display substrate DS thereon in case that the display substrate DS is seated on the mask assembly MA, and are able to linearly move the display substrate DS and the mask assembly MA.

However, hereinafter, for convenience of description, a case, in which the first support portion SP1 and the second support portion SP2 are formed to be separated from each other and arranged at different positions in the chamber CH, and the first support portion SP1 and the second support portion SP2 are arranged inside the chamber CH, is described in detail.

The mask assembly MA may be arranged inside the chamber CH to face the display substrate DS. A deposition material M may be deposited on the display substrate DS through the mask assembly MA.

The deposition source unit SC may be arranged to face the mask assembly MA, and may supply the deposition material M such that the deposition material M may be deposited on the display substrate DS by passing through the mask assembly MA. For example, the deposition source unit SC may evaporate or sublimate the deposition material M by applying heat to the deposition material M. The deposition source unit SC may be arranged to be fixed inside the chamber CH or arranged inside the chamber CH to be able to linearly move in a direction.

The magnetic force unit MG may be arranged inside the chamber CH to face the display substrate DS and/or the mask assembly MA. For example, the magnetic force unit MG may press the mask assembly MA toward the side of the display substrate DS by applying a magnetic force to the mask assembly MA.

The vision unit VS may be arranged in the chamber CH and may capture an image of the positions of the display substrate DS and the mask assembly MA. For example, the vision unit VS may include a camera that captures an image of the display substrate DS and the mask assembly MA. Based on the image captured by the vision unit VS, the positions of the display substrate DS and the mask assembly MA may be determined, and the transformation of the mask assembly MA may be confirmed. For example, based on the image, the position of the display substrate DS may be finely adjusted by the first support portion SP1, and the position of the mask assembly MA may be finely adjusted by the second support portion SP2. However, hereinafter, a case in which the positions of the display substrate DS and the mask assembly MA are aligned with each other by finely adjusting the position of the mask assembly MA by the second support portion SP2 is described in detail.

The pressure adjusting unit PSC may be connected to the chamber CH to adjust the inner pressure of the chamber CH. For example, the pressure adjusting unit PSC may adjust the inner pressure of the chamber CH to be equal to or similar to atmospheric pressure. For example, the pressure adjusting unit PSC may adjust the inner pressure of the chamber CH to be same as or similar to a vacuum state.

The pressure adjusting unit PSC may include a connection pipe 81 connected to the chamber CH and a pump 82 installed in the connection pipe 81. For example, depending on an operation of the pump 82, external air may be introduced (or transferred) to the chamber CH through the connection pipe 81, or a gas inside the chamber CH may be guided to the outside through the connection pipe 81.

Referring to a method of manufacturing a display device by using the apparatus 1 for manufacturing a display device as described above, the display substrate DS may be prepared.

The pressure adjusting unit PSC may maintain the inside of the chamber CH in a state that is equal to or similar to atmospheric pressure, and the gate valve GB may operate to open the open portion (e.g., entrance, door, or opening and closing same) of the chamber CH.

Thereafter, the display substrate DS may be charged (or transferred) into the chamber CH from the outside. For example, the display substrate DS may be charged (or transferred) into the chamber CH in various ways. For example, the display substrate DS may be charged (or transferred) into the chamber CH from the outside of the chamber CH by a robot arm arranged outside the chamber CH. In another example, in case that the first support portion SP1 is formed in a shuttle shape, after the first support portion SP1 is carried out from the inside of the chamber CH to the outside of the chamber CH, the display substrate DS may be seated on the first support portion SP1, and the first support portion SP1 may be charged (or transferred) into the chamber CH from the outside of the chamber CH, by a separate robot arm or the like arranged outside the chamber CH.

The mask assembly MA may be arranged inside the chamber CH as described above. In another example, the mask assembly MA may also be charged (or transferred) into the chamber CH from the outside of the chamber CH in the same or similar manner to the display substrate DS.

In case that the display substrate DS is charged (or transferred) into the chamber CH, the display substrate DS may be seated on the first support portion SP1. For example, the vision unit VS may capture an image of the positions of the display substrate DS and the mask assembly MA. The positions of the display substrate DS and the mask assembly MA may be determined based on the image captured by the vision unit VS. For example, the apparatus 1 for manufacturing a display device may include a separate controller to determine the positions of the display substrate DS and the mask assembly MA.

In case that the positions of the display substrate DS and the mask assembly MA are determined, the second support portion SP2 may finely adjust the position of the mask assembly MA.

Thereafter, the deposition source unit SC may operate to supply the deposition material M to a side of the mask assembly MA, and the deposition material M passing through the mask assembly MA may be deposited on the display substrate DS. For example, the deposition source unit SC may move parallel to the display substrate DS and the mask assembly MA, or the display substrate DS and the mask assembly MA may move parallel to the deposition source unit SC. For example, the deposition source unit SC may move relatively to the display substrate DS and the mask assembly MA. For example, the pump 82 may maintain the inner pressure of the chamber CH in a state that is same as or similar to a vacuum state by absorbing and discharging a gas inside the chamber CH to the outside.

As described above, the deposition material M supplied from the deposition source unit SC may be deposited on the display substrate DS by passing through the mask assembly MA, and accordingly, a plurality of layers to be deposited on a display device to be described below, for example, at least one of an organic layer, an inorganic layer, and metal layer, may be formed.

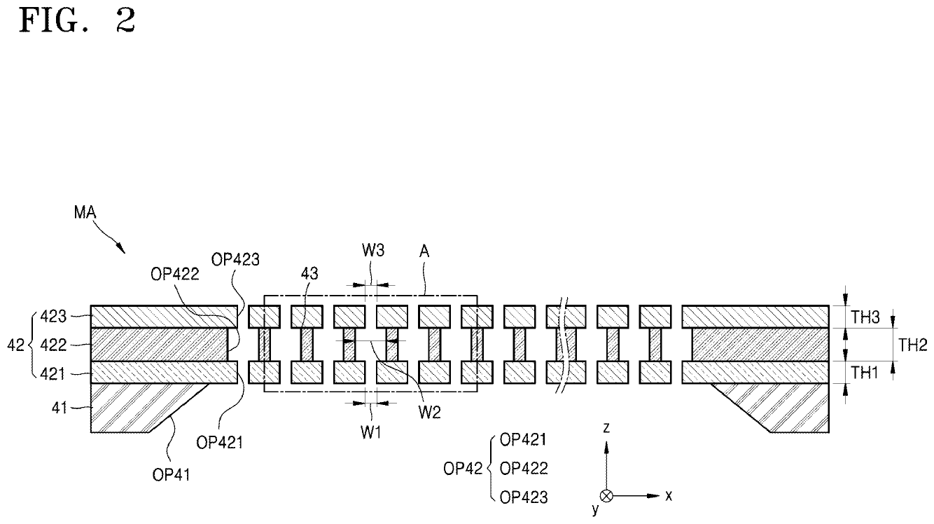

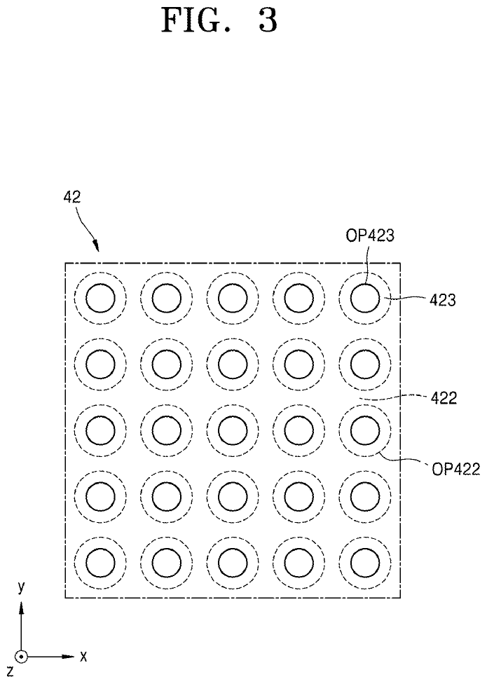

FIG. 2 is a schematic cross-sectional view of a mask assembly according to an embodiment, and FIG. 3 is a schematic plan view of a portion of a second mask layer according to an embodiment. FIG. 3 is a diagram of a region A of FIG. 2 as viewed from above (e.g., in a plan view).

Referring to FIGS. 2 and 3, the mask assembly MA may include a first mask layer 41 and a second mask layer 42.

The first mask layer 41 may support the second mask layer 42. A first mask opening OP41 may be arranged in the first mask layer 41 such that the deposition material M (refer to FIG. 1) may pass therethrough. An inner peripheral surface may be formed in the first mask layer 41 by the first mask opening OP41. The first mask opening OP41 may be arranged at a central portion of the first mask layer 41. A central portion of the second mask layer 42 may be exposed through the first mask opening OP41 of the first mask layer 41. FIG. 2 shows that the inner peripheral surface of the first mask layer 41 is inclined with respect to the second mask layer 42 in a cross-sectional view, but this is only an example, and the inner peripheral surface of the first mask layer 41 may be perpendicular to the second mask layer 42.

The first mask layer 41 may include a silicon material. For example, the first mask layer 41 may include at least one material of silicon oxide (SiOₓ), silicon nitride (SiNₓ), and silicon oxynitride (SiOₓN_{y}).

The second mask layer 42 may be disposed on the first mask layer 41. A second mask opening OP42 may be arranged in the second mask layer 42 such that the deposition material M (refer to FIG. 1) may pass therethrough. The second mask opening OP42 may overlap the first mask opening OP41. Second mask openings OP42 may be provided. For example, as shown in FIG. 3, the second mask openings OP42 may be arranged in a first direction (e.g., an x-axis direction) and a second direction (e.g., a y-axis direction). The second mask layer 42 may include a first inorganic layer 421, a first organic layer 422, and a second inorganic layer 423.

The first inorganic layer 421 may be disposed on the first mask layer 41. For example, the first inorganic layer 421 may include at least one material of silicon oxide (SiOₓ), silicon nitride (SiNₓ), and silicon oxynitride (SiOₓN_{y}).

The first organic layer 422 may be disposed on the first inorganic layer 421. The first organic layer 422 may include at least one material of polyimide (PI), polyester, and acrylic.

In a cross-sectional view, a thickness TH2 of the first organic layer 422 may be greater than a thickness TH1 of the first inorganic layer 421 and a thickness TH3 of the second inorganic layer 423. For example, a length of the first organic layer 422 in a third direction (e.g., a z-axis direction) may be greater than the thickness TH1 of the first inorganic layer 421 and the thickness TH3 of the second inorganic layer 423 in the third direction (e.g., the z-axis direction). Due to the arrangement of the first organic layer 422, a thickness of the second mask layer 42 may be readily adjusted, and the durability of the second mask layer 42 may be improved.

The second inorganic layer 423 may be disposed on the first organic layer 422. The second inorganic layer 423 and the first inorganic layer 421 may include the same material. In a cross-sectional view, the thickness TH3 of the second inorganic layer 423 may be substantially equal to the thickness TH1 of the first inorganic layer 421. For example, the length of the second inorganic layer 423 in the third direction (e.g., the z-axis direction) may be substantially equal to the length of the first inorganic layer 421 in the third direction (e.g., the z-axis direction).

The second mask opening OP42 may include a first inorganic opening OP421, a first organic opening OP422, and a second inorganic opening OP423. The first inorganic opening OP421 may be arranged in the first inorganic layer 421, the first organic opening OP422 may be arranged in the first organic layer 422, and the second inorganic opening OP423 may be arranged in the second inorganic layer 423.

The first inorganic opening OP421, the first organic opening OP422, and the second inorganic opening OP423 may overlap each other. Accordingly, the deposition material M (refer to FIG. 1) may sequentially pass through the first inorganic opening OP421, the first organic opening OP422, and the second inorganic opening OP423.

In a cross-sectional view, a width W2 of the first organic opening OP422 may be greater than a width W1 of the first inorganic opening OP421 and a width W3 of the second inorganic opening OP423. In a plan view, an area of the first organic opening OP422 may be greater than an area of the first inorganic opening OP421 and an area of the second inorganic opening OP423. For example, in a cross-sectional view, the size of the width W1 of the first inorganic opening OP421 may be the same as the size of the width W3 of the second inorganic opening OP423. In a plan view, the area/size of the first inorganic opening OP421 may be substantially equal to the area/size of the second inorganic opening OP423.

In such a structure, a first step portion 43 may be formed in the first organic layer 422 and the second inorganic layer 423. The first step portion 43 may include at least a portion of a surface of the first organic layer 422 and a surface of the second inorganic layer 423. The first step portion 43 may be arranged around the first organic opening OP422 and the second inorganic opening OP423. In a cross-sectional view, a shape of the first step portion 43 may have a ‘¬’ shape.

At least a portion of the deposition material M (refer to FIG. 1) supplied from the deposition source unit SC (refer to FIG. 1) may be accumulated in the second mask opening OP42 without passing through the second mask opening OP42. For example, at least a portion of the deposition material M (refer to FIG. 1), which is accumulated in the second mask opening OP42, may be accumulated on the first step portion 43. For example, due to the first step portion 43, a phenomenon in which the deposition material M (refer to FIG. 1) blocks the second mask opening OP42 may be reduced. Accordingly, although there is no separate cleaning process of the mask assembly MA, the usage time (or lifespan) of the mask assembly MA may increase.

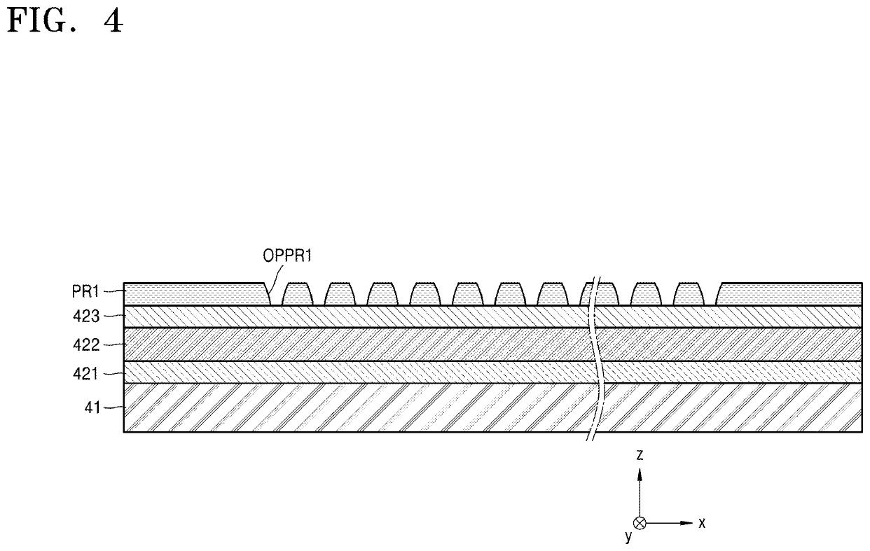

FIGS. 4 to 11 are cross-sectional views for explaining a method of manufacturing a display device according to an embodiment.

Referring to FIGS. 4 to 11, the same reference numerals as those in FIGS. 1 to 3 refer to the same members, and redundant descriptions thereof are omitted for descriptive convenience.

Referring to FIGS. 4 to 11, the method of manufacturing a display device may include arranging the mask assembly MA inside the chamber CH (refer to FIG. 1). The arranging of the mask assembly MA may include disposing the second mask layer 42 on the first mask layer 41, forming the first mask opening OP41 in the first mask layer 41, and forming the second mask opening OP42 in the second mask layer 42.

Referring to FIG. 4, the disposing of the second mask layer 42 on the first mask layer 41 may include disposing the first inorganic layer 421 on the first mask layer 41, disposing the first organic layer 422 on the first inorganic layer 421, and disposing the second inorganic layer 423 on the first organic layer 422. For example, the first inorganic layer 421 may be deposited on the first mask layer 41, the first organic layer 422 may be deposited on the first inorganic layer 421, and the second inorganic layer 423 may be deposited on the first organic layer 422.

Referring to FIGS. 4 to 6, the forming of the second mask opening OP42 may include forming the second inorganic opening OP423 in the second inorganic layer 423. The second inorganic opening OP423 may be formed by a photolithography process.

Referring to FIG. 4, the forming of the second inorganic opening OP423 may include disposing a first photoresist layer PR1, in which a first photo-opening OPPR1 is arranged, on the second inorganic layer 423. After the first photoresist layer PR1 is disposed on the second inorganic layer 423, the first photoresist layer PR1 is exposed through a patterned mask, and then the first photo-opening OPPR1 may be formed by a process of removing a portion of the first photoresist layer PR1.

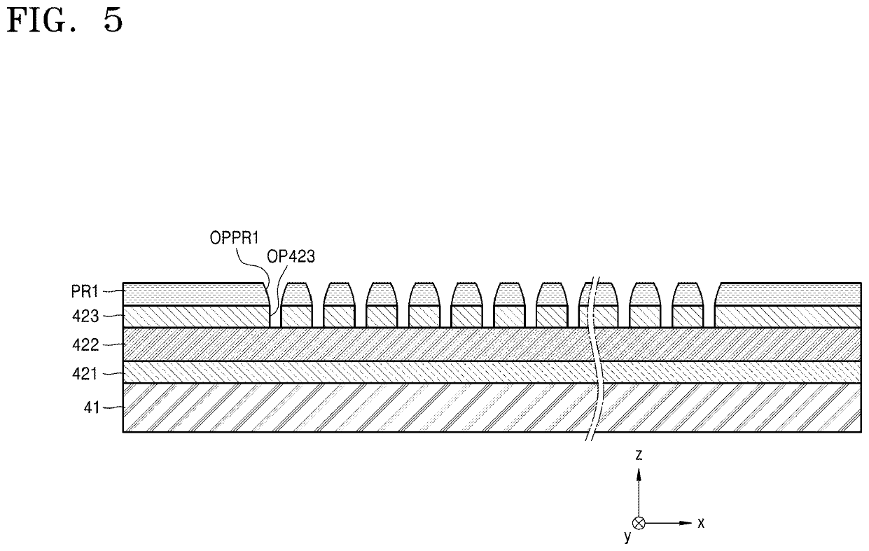

Referring to FIG. 5, the forming of the second inorganic opening OP423 may include etching the second inorganic layer 423 overlapping the first photo-opening OPPR1. A portion of the second inorganic layer 423, which overlaps the first photo-opening OPPR1, may be removed by an etching process. For example, a portion of the second inorganic layer 423 may be removed by a dry etching process.

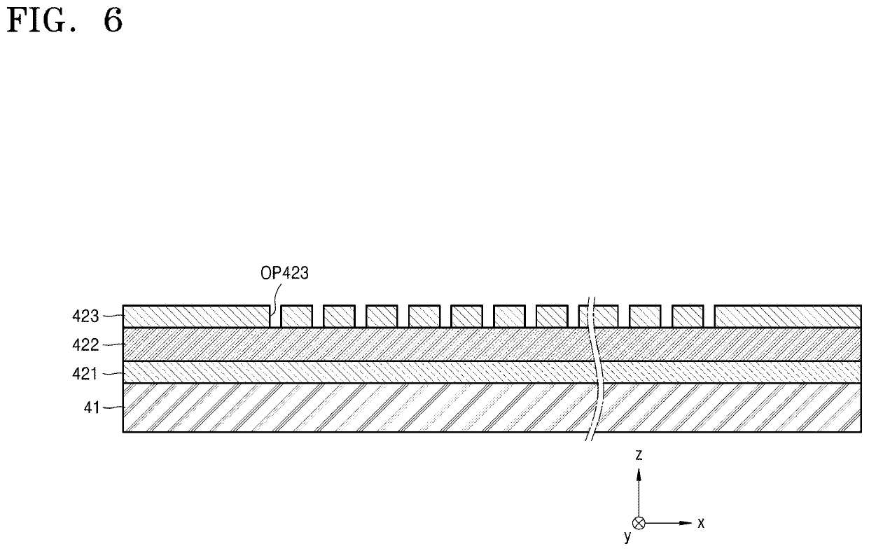

Referring to FIG. 6, the forming of the second inorganic opening OP423 may include removing the first photoresist layer PR1 (refer to FIG. 5). The first photoresist layer PR1 (refer to FIG. 5) remaining on the second inorganic layer 423 may be removed (e.g., entirely removed).

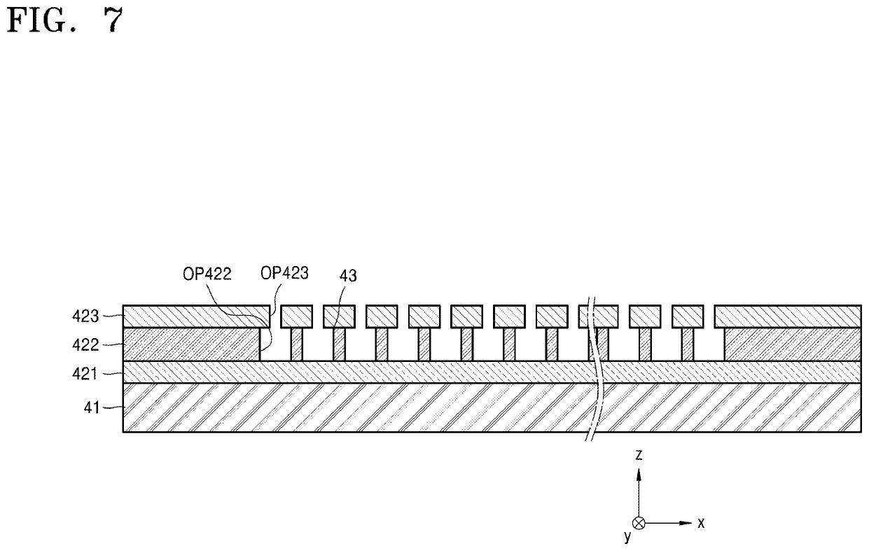

Referring to FIG. 7, the forming of the second mask opening OP42 may include forming the first organic opening OP422 in the first organic layer 422. The forming of the first organic opening OP422 may include etching the first organic layer 422 overlapping the second inorganic opening OP423. A portion of the first organic layer 422, which overlaps the second inorganic opening OP423, may be removed by an etching process. For example, a portion of the first organic layer 422 may be removed by a wet etching process. For example, due to an etching solution, a width W2 of the first organic opening OP422 may be greater than a width W3 of the second inorganic opening OP423 in a cross-sectional view.

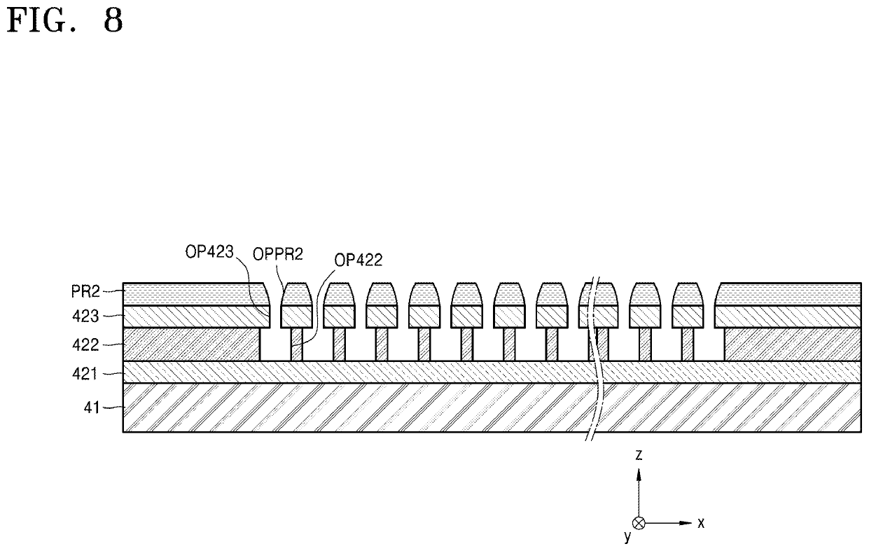

Referring to FIGS. 8 to 10, the forming of the second mask opening OP42 may include forming the first inorganic opening OP421 in the first inorganic layer 421. The first inorganic opening OP421 may be formed by a photolithography process.

Referring to FIG. 8, the forming of the first inorganic opening OP421 may include disposing a second photoresist layer PR2, in which a second photo-opening OPPR2 is arranged, on the second inorganic layer 423. The second photo-opening OPPR2 may overlap the second inorganic opening OP423. In a plan view, the second photo-opening OPPR2 may have the same size and shape as that of the second inorganic opening OP423.

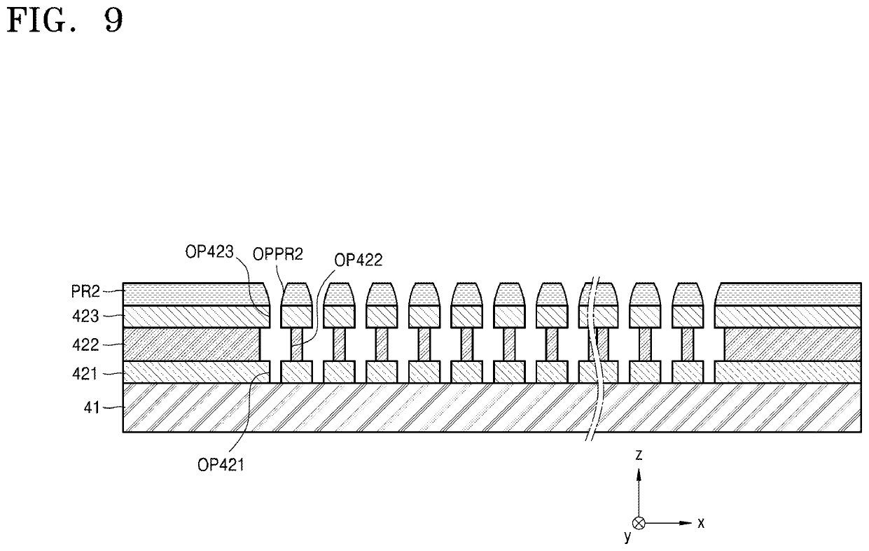

Referring to FIG. 9, the forming of the first inorganic opening OP421 may include etching the first inorganic layer 421 overlapping the second photo-opening OPPR2. For example, the forming of the first inorganic opening OP421 may include etching the first inorganic layer 421 overlapping the second inorganic opening OP423. A portion of the first inorganic layer 421, which overlaps the second inorganic opening OP423, may be removed by an etching process. For example, a portion of the first inorganic layer 421 may be removed by the dry etching process described above. For example, in a cross-sectional view, the size of the width W1 of the first inorganic opening OP421 and the size of the width W3 of the second inorganic opening OP423 may be the same as each other.

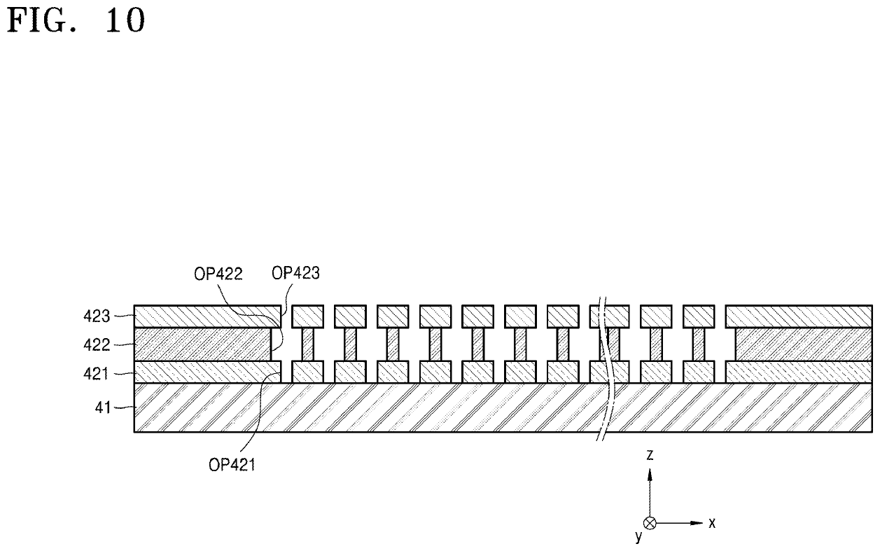

Referring to FIG. 10, the forming of the first inorganic opening OP421 may include removing the second photoresist layer PR2 (refer to FIG. 9). The second photoresist layer PR2 (refer to FIG. 9) remaining on the second inorganic layer 423 may be removed (e.g., entirely removed).

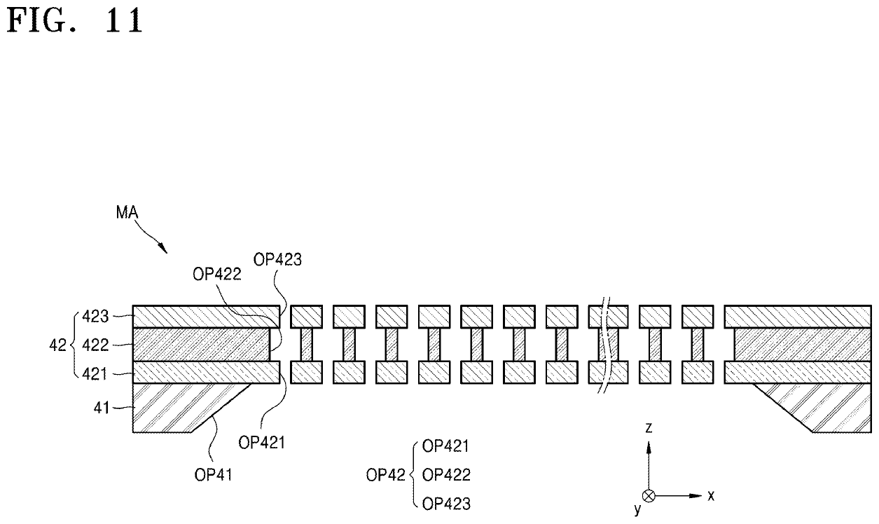

Referring to FIG. 11, the first mask opening OP41 may be formed by a photolithography process. A portion of the first mask layer 41 may be removed by an etching process. For example, a portion of the first mask layer 41 may be removed by the dry etching process or wet etching process described above.

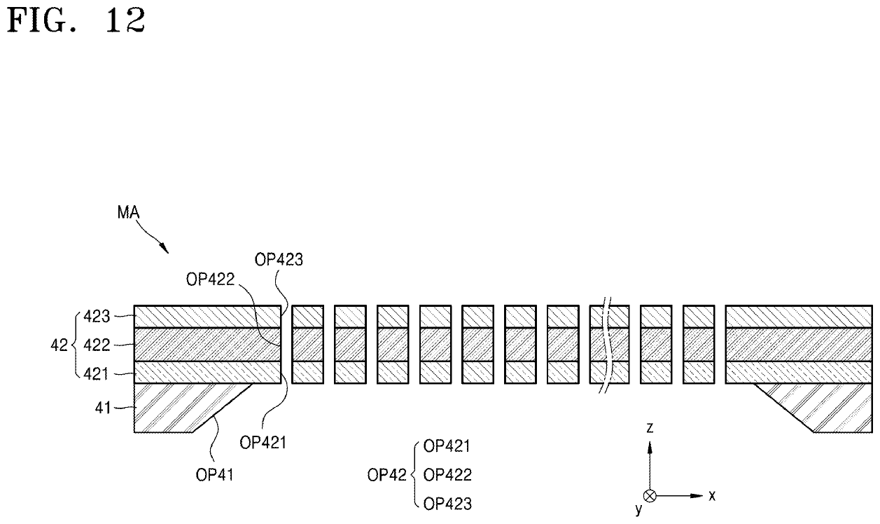

FIG. 12 is a schematic cross-sectional view of the mask assembly MA according to another embodiment.

In FIG. 12, the same reference numerals as those in FIG. 2 refer to the same members, and redundant description thereof are omitted for descriptive convenience.

Referring to FIG. 12, in a cross-sectional view, the sizes of the widths W1, W2, and W3 of the first inorganic opening OP421, the first organic opening OP422, and the second inorganic opening OP423 may be same as each other. In a plan view, areas of the first inorganic opening OP421, the first organic opening OP422, and the second inorganic opening OP423 may be substantially equal to each other.

However, the shape of the second mask opening OP42 shown in FIGS. 2 to 12 is only an example, and the shape of the second mask opening OP42 is not limited thereto. For example, unlike those shown in FIGS. 2 to 12, in a cross-sectional view, the width W2 of the first organic opening OP422 may be less than the width W1 of the first inorganic opening OP421 and the width W3 of the second inorganic opening OP423, and may also have various shapes.

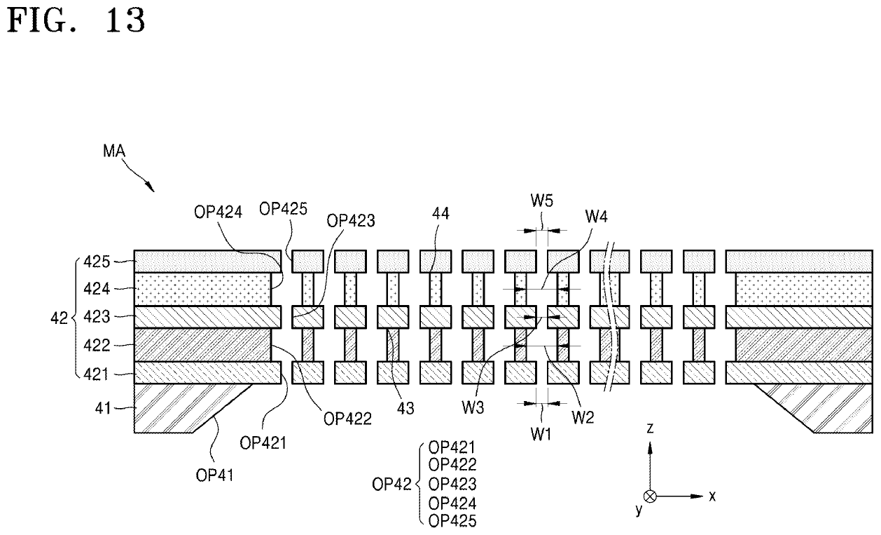

FIG. 13 is a schematic cross-sectional view of a mask assembly according to another embodiment.

In FIG. 13, the same reference numerals as those in FIG. 2 refer to the same members, and redundant descriptions thereof are omitted for descriptive convenience.

Referring to FIG. 13, the second mask layer 42 may include the first inorganic layer 421, the first organic layer 422, the second inorganic layer 423, a second organic layer 424, and a third inorganic layer 425. The second organic layer 424 may be disposed on the second inorganic layer 423, and the third inorganic layer 425 may be disposed on the second organic layer 424. The first inorganic layer 421, the second inorganic layer 423, and the third inorganic layer 425 may include the same material. The first organic layer 422 and the second organic layer 424 may include the same material.

For example, the second mask opening OP42 may include the first inorganic opening OP421, the first organic opening OP422, the second inorganic opening OP423, a second organic opening OP424, and a third inorganic opening OP425. The second organic opening OP424 may be arranged in the second organic layer 424, and the third inorganic opening OP425 may be arranged in the third inorganic layer 425.

The first inorganic opening OP421, the first organic opening OP422, the second inorganic opening OP423, the second organic opening OP424, and the third inorganic opening OP425 may overlap each other. Accordingly, the deposition material M (refer to FIG. 1) may sequentially pass through the first inorganic opening OP421, the first organic opening OP422, the second inorganic opening OP423, the second organic opening OP424, and the third inorganic opening OP425.

In a cross-sectional view, a width W4 of the second organic opening OP424 may be greater than a width W1 of the first inorganic opening OP421, a width W3 of the second inorganic opening OP423, and a width W5 of the third inorganic opening OP425. In a plan view, an area of the second organic opening OP424 may be greater than an area of each of the first inorganic opening OP421, the second inorganic opening OP423, and the third inorganic opening OP425. For example, in a cross-sectional view, the sizes of the widths W1, W3, and W5 of the first inorganic opening OP421, the second inorganic opening OP423, and the third inorganic opening OP425 may be same as each other. In a plan view, the areas of the first inorganic opening OP421, the second inorganic opening OP423, and the third inorganic opening OP425 may be substantially equal to each other.

In such a structure, a second step portion 44 may be formed in the second organic layer 424 and the third inorganic layer 425. The second step portion 44 may include at least a portion of a surface of the second organic layer 424 and a surface of the third inorganic layer 425. The second step portion 44 may be arranged around the second organic opening OP424 and the third inorganic opening OP425. In a cross-sectional view, a shape of the second step portion 44 may have a ‘¬’ shape.

At least a portion of the deposition material M (refer to FIG. 1) supplied from the deposition source unit SC (refer to FIG. 1) may be accumulated in the second mask opening OP42 without passing through the second mask opening OP42. For example, at least a portion of the deposition material M (refer to FIG. 1), which is accumulated in the second mask opening OP42, may be accumulated on the first step portion 43 and the second step portion 44. For example, due to the first step portion 43 and the second step portion 44, a phenomenon in which the deposition material M (refer to FIG. 1) blocks the second mask opening OP42 may be reduced. Accordingly, although there is no separate cleaning process of the mask assembly MA, the usage time (or lifespan) of the mask assembly MA may increase.

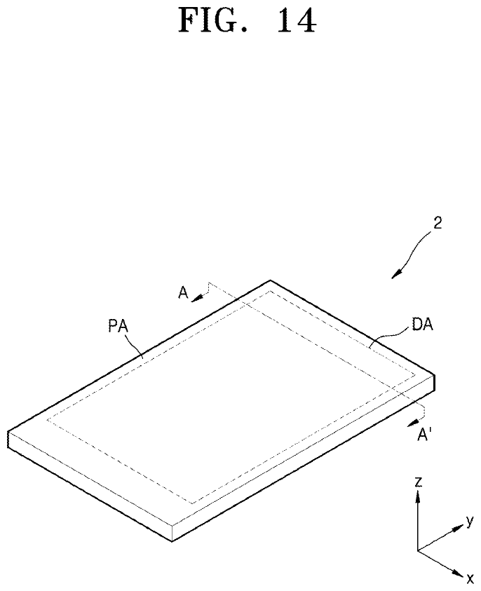

FIG. 14 is a schematic perspective view of a display device according to an embodiment.

Referring to FIG. 14, a display device 2 may include a display area DA and a peripheral area PA surrounding the display area DA. The display device 2 may provide a certain image by using light emitted from pixels arranged in the display area DA.

The peripheral area PA may surround (e.g., entirely surround) the display area DA. The peripheral area PA may be a kind of non-display area in which pixels are not arranged, and drivers or lines for providing electrical signals or power to the pixels may be arranged therein.

As shown in FIG. 14, the display device 2 may have a rectangular shape in which a horizontal length is greater than a vertical length, but embodiments are not limited thereto. The display device 2 may have various shapes such as a polygonal shape, a circular shape, or an elliptical shape.

Hereinafter, the display device 2 according to an embodiment is described as an organic light-emitting display device as an example, but embodiments are not limited thereto. In another example, a display device of another type, such as a quantum dot light-emitting display, may be used.

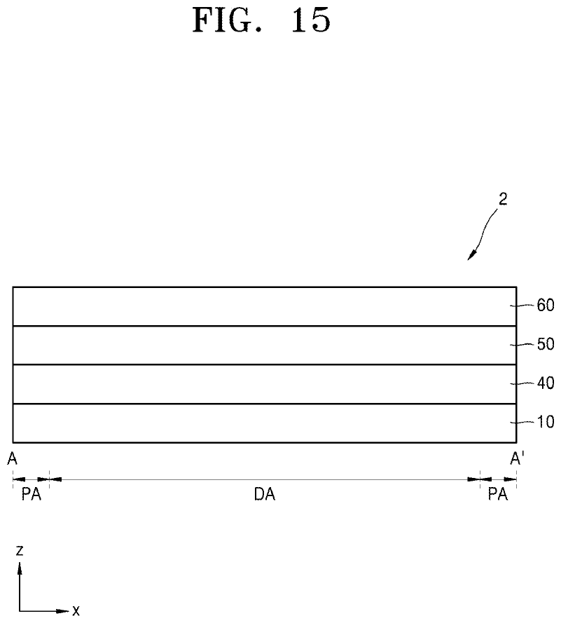

FIG. 15 is a schematic cross-sectional view of a display device according to an embodiment. FIG. 15 is a cross-sectional view of the display device 2 taken along line A-A′ of FIG. 14.

Referring to FIG. 15, the display device 2 may include a display panel 10, an input sensing layer 40 disposed on the display panel 10, and an optical functional layer 50. The display panel 10, the input sensing layer 40, and the optical functional layer 50 may be covered by a window 60. The display device 2 may be various types of electronic devices, such as a mobile phone, a notebook computer, and a smart watch.

The display panel 10 may display an image. The display panel 10 may include pixels arranged in the display area DA. The pixels may include a display element and a pixel circuit connected to the display element. The display element may include an organic light-emitting diode, a quantum dot organic light-emitting diode, or the like.

The input sensing layer 40 may obtain (or collect) coordinate information according to an external input, for example, a touch event. The input sensing layer 40 may include a sensing electrode (or touch electrode) and a trace line connected to the sensing electrode. The input sensing layer 40 may be disposed on the display panel 10. The input sensing layer 40 may sense an external input in a mutual-capacitive method and/or a self-capacitive method.

The input sensing layer 40 may be formed (e.g., directly formed) on the display panel 10 or formed separately and then bonded to the display panel 10 through an adhesive layer such as an optical clear adhesive. For example, the input sensing layer 40 may be formed continuously after a process of forming the display panel 10. For example, the input sensing layer 40 may be formed as a portion of the display panel 10, and an adhesive layer may not be between the input sensing layer 40 and the display panel 10. FIG. 15 illustrates that the input sensing layer 40 is between the display panel 10 and the optical functional layer 50, but the input sensing layer 40 may also be disposed above the optical functional layer 50 in another example.

The optical functional layer 50 may include an anti-reflection layer. The anti-reflection layer may reduce the reflectance of light incident from the outside (e.g., external light) toward the display panel 10 through the window 60. In an embodiment, the anti-reflection layer may include a black matrix and color filters. The color filters may be arranged according to the color of light emitted from each of the pixels of the display panel 10.

In another example, the anti-reflection layer may include a retarder and a polarizer. The retarder may be a film type or a liquid-crystal coating type, and may include a λ/2 retarder and/or a λ/4 retarder. The polarizer may also be a film type or a liquid-crystal coating type. The film-type polarizer may include a stretch-type synthetic resin film, and the liquid-crystal-coating-type polarizer may include liquid crystals in a certain arrangement. The retarder and the polarizer may further include a protective film. The retarder and the polarizer or the protective film may be defined as a base layer of the anti-reflection layer.

In another example, the anti-reflection layer may include a destructive interference structure. The destructive interference structure may include a first reflective layer and a second reflective layer arranged on different layers. First reflected light and second reflected light respectively reflected from the first reflective layer and the second reflective layer may destructively interfere, and thus, the reflectance of external light may be reduced.

In an embodiment, the optical functional layer 50 may be formed continuously after a process of forming the display panel 10 and/or the input sensing layer 40. For example, the adhesive layer may not be between the optical functional layer 50 and the input sensing layer 40 and/or between the input sensing layer 40 and the display panel 10.

For example, a layer including an optical clear adhesive or an optical clear resin may be between the window 60 and the optical functional layer 50.

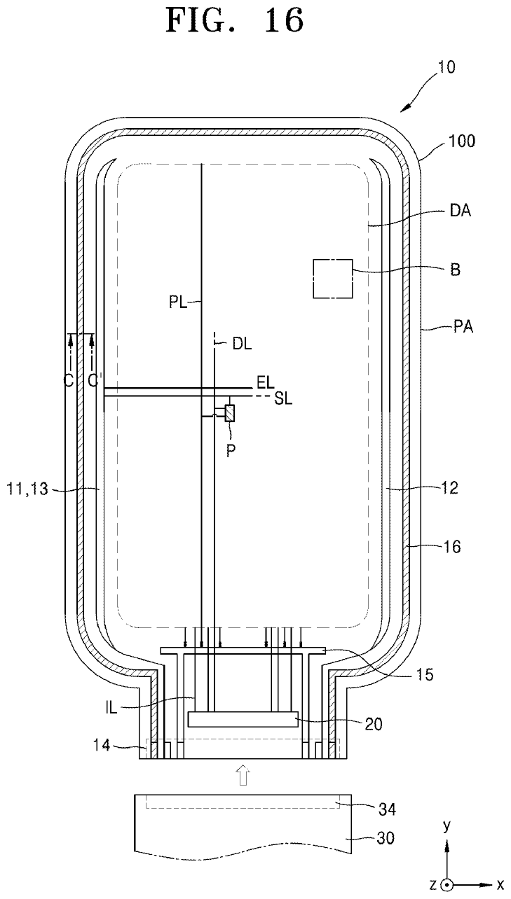

FIG. 16 is a schematic plan view of a display panel according to an embodiment. As described above with reference to FIG. 15, a display device according to an embodiment may include the display panel 10. FIG. 16 may illustrate a view of a substrate 100 of the display panel 10.

Referring to FIG. 16, the display panel 10 may include the display area DA and the peripheral area PA outside the display area DA. The display area DA may be a portion that displays an image, and pixels P may be arranged in the display area DA. The display area DA have various shapes, for example, a circular shape, an oval shape, a polygonal shape, a shape of a certain figure, or the like. In FIG. 16, the display area DA is shown to have a substantially rectangular shape with rounded corners.

Each of the pixels P refers to a sub-pixel, and may include a display element such as an organic light-emitting diode (OLED). The pixel P may emit, for example, red, green, blue, or white light.

The peripheral area PA may be arranged outside the display area DA. Outer circuits for driving the pixels P may be arranged in the peripheral area PA. A first scan driving circuit 11, a second scan driving circuit 12, an emission control driving circuit 13, a terminal 14, a driving power supply line 15, and a common power supply line 16 may be arranged in the peripheral area PA.

The first scan driving circuit 11 may provide a scan signal to the pixel P through a scan line SL. The second scan driving circuit 12 may be arranged in parallel with the first scan driving circuit 11 with the display area DA therebetween. Some of the pixels P arranged in the display area DA may be electrically connected to the first scan driving circuit 11, and the remaining pixels P may be connected to the second scan driving circuit 12. For example, the second scan driving circuit 12 may be omitted, and all of the pixels P arranged in the display area DA may be electrically connected to the first scan driving circuit 11.

The emission control driving circuit 13 may be arranged on a side of the first scan driving circuit 11 and provide an emission control signal to the pixel P through an emission control line EL. Although FIG. 14 illustrates that the emission control driving circuit 13 is arranged only on a side of the display area DA, the emission control driving circuit 13 may be arranged on both sides of the display area DA, similar to the first scan driving circuit 11 and the second scan driving circuit 12.

In an embodiment, the peripheral area PA may include a bending area extending toward a side of the display area DA (in a negative y-axis direction). The bending area may be bent toward a rear surface of the display area DA, so that an area (or size) of the non-display area that is visible when viewed from a front surface of the display device may be reduced.

A driving chip 20 may be arranged in the peripheral area PA. The driving chip 20 may include an integrated circuit that drives the display panel 10. The integrated circuit may be a data driving integrated circuit that generates data signals, but embodiments are not limited thereto.

The terminal 14 may be arranged in the peripheral area PA. The terminal 14 may be exposed by not being covered by an insulating layer and may be electrically connected to a printed circuit board 30. A terminal 34 of the printed circuit board 30 may be electrically connected to the terminal 14 of the display panel 10.

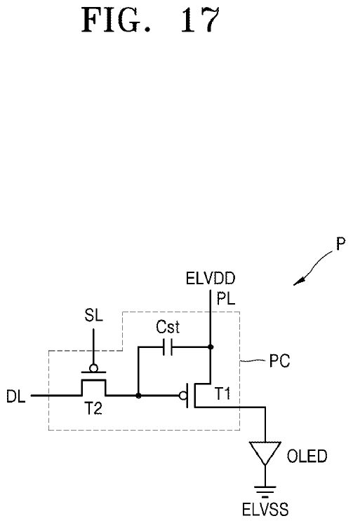

The printed circuit board 30 may transmit a signal or power of a controller to the display panel 10. A control signal generated by the controller may be transmitted to each of the first and second scan driving circuits 11 and 12 and the emission control driving circuit 13 through the printed circuit board 30. For example, the controller may transmit a driving voltage ELVDD (refer to FIG. 17) to the driving power supply line 15 and provide a common voltage ELVSS (refer to FIG. 17) to the common power supply line 16. The driving voltage ELVDD may be transferred to each pixel P through a driving voltage line PL connected to the driving power supply line 15, and the common voltage ELVSS may be transferred to an opposite electrode of the pixel P connected to the common power supply line 16. The driving power supply line 15 may have a shape extending in a direction (e.g., x-axis direction) from a lower side of the display area DA. The common power supply line 16 may have a loop shape with a side open to partially surround the display area DA.

The controller may generate a data signal, and the generated data signal may be transferred to an input line IL through the driving chip 20 and to the pixel P through a data line DL connected to the input line IL. For reference, “line” may mean “wire”. The above description is similar to the embodiments and modification examples thereof to be described below.

FIG. 17 is a schematic diagram of an equivalent circuit of a pixel included in a display device according to an embodiment.

Referring to FIG. 17, a pixel P may include a pixel circuit PC and an organic light-emitting diode OLED as a display element connected to the pixel circuit PC. The pixel circuit PC may include a first thin-film transistor T1, a second thin-film transistor T2, and a storage capacitor Cst. Each pixel P may emit, for example, red light, green light, or blue light, or may emit red light, green light, blue light, or white light, through the organic light-emitting diode OLED.

The second thin-film transistor T2 may be a switching thin-film transistor, which is connected to a scan line SL and the data line DL and transfers, to the first thin-film transistor T1, a data voltage input from the data line DL based on a switching voltage input from the scan line SL. The storage capacitor Cst may be connected to the second thin-film transistor T2 and the driving voltage line PL and may store a voltage corresponding to a difference between a voltage received from the second thin-film transistor T2 and the driving voltage ELVDD supplied to the driving voltage line PL.

The first thin-film transistor T1 may be a driving thin-film transistor, which is connected to the driving voltage line PL and the storage capacitor Cst and controls a driving current flowing from the driving voltage line PL through the organic light-emitting diode OLED, in accordance with a voltage value stored in the storage capacitor Cst. The organic light-emitting diode OLED may emit light having a certain brightness according to the driving current. An opposite electrode (e.g., a cathode) of the organic light-emitting diode OLED may receive the common voltage ELVSS.

FIG. 17 illustrates that the pixel circuit PC includes two thin-film transistors and one storage capacitor, but embodiments are not limited thereto. The number of thin-film transistors and the number of storage capacitors may be variously changed according to the design of the pixel circuit PC. For example, the pixel circuit PC may further include four or more thin-film transistors in addition to the above-mentioned two thin-film transistors.

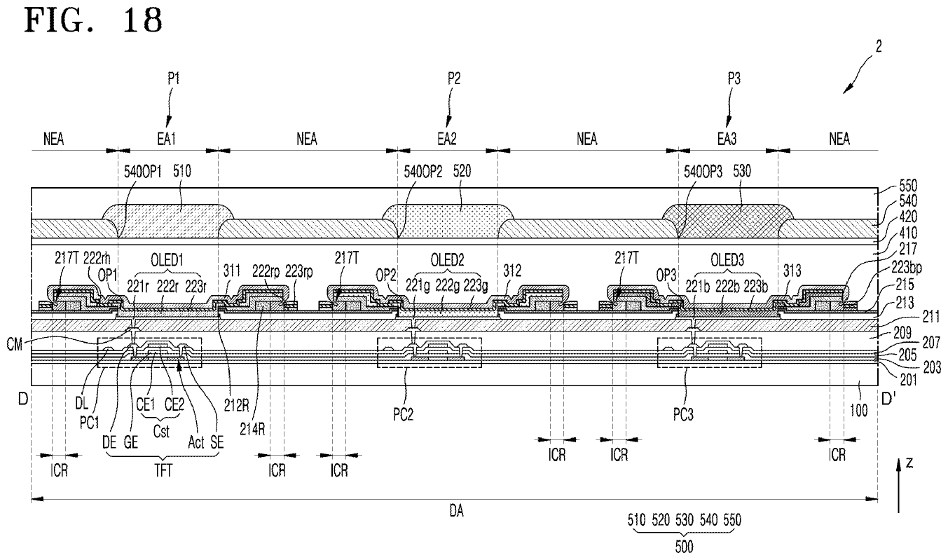

FIG. 18 is a schematic cross-sectional view of a display device according to an embodiment.

Referring to FIG. 18, the display panel device 2 may include the substrate 100.

The substrate 100 may include a glass material or a polymer resin. In an embodiment, the substrate 100 may have a multi-layered structure in which a base layer including a polymer resin and a barrier layer preventing penetration of external materials are cross-stacked.

The base layer may include a polymer resin, such as polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose triacetate (TAC), cellulose acetate propionate (CAP), or the like.

The barrier layer may include an inorganic material such as silicon nitride (SiNₓ) and silicon oxide (SiOₓ).

In the display area DA of the substrate 100, a first pixel P1 emitting light in a first color, a second pixel P2 emitting light in a second color, and a third pixel P3 emitting light in a third color. The first color, the second color, and the third color may be any one of red, blue, green, or white.

The first pixel P1 may include a first pixel circuit PC1 and a first organic light-emitting diode OLED1 as a display element electrically connected to the first pixel circuit PC1. The second pixel P2 may include a second pixel circuit PC2 and a second organic light-emitting diode OLED2 electrically connected to the second pixel circuit PC2. The third pixel P3 may include a third pixel circuit PC3 and a third organic light-emitting diode OLED3 electrically connected to the third pixel circuit PC3.

A buffer layer 201 may be formed on the substrate 100 to prevent impurities from penetrating into a semiconductor layer Act of a thin-film transistor TFT of the first pixel circuit PC1. The buffer layer 201 may include an inorganic insulating material such as silicon nitride (SiNₓ), silicon oxynitride (SiOₓN_{y}), and silicon oxide (SiOₓ), and may include a single layer or a multi-layer that includes the material described above.

The first pixel circuit PC1, the second pixel circuit PC2, and the third pixel circuit PC3 may be disposed on the buffer layer 201. The first pixel circuit PC1 may include the thin-film transistor TFT and the storage capacitor Cst. The thin-film transistor TFT may include the semiconductor layer Act, a gate electrode GE, a source electrode SE, and a drain electrode DE. The thin-film transistor TFT shown in FIG. 18 may correspond to the first thin-film transistor described with reference to FIG. 17. The data line DL may be electrically connected to a second thin-film transistor of the first pixel circuit PC1. In an embodiment, a top-gate type in which the gate electrode GE may be disposed above the semiconductor layer Act with a gate insulating layer 203 between the gate electrode GE and the semiconductor layer Act, but according to another example, the thin-film transistor TFT may be a bottom-gate type. The second pixel circuit PC2 and the third pixel circuit PC3 may be the same as or similar to the first pixel circuit PC1. Hereinafter, each component of the first pixel circuit PC1 is described.

The semiconductor layer Act may include polysilicon. In another example, the semiconductor layer Act may include amorphous silicon, an oxide semiconductor, an organic semiconductor, or the like. The gate electrode GE may include a low-resistance metal material. The gate electrode GE may include a conductive material including molybdenum (Mo), aluminum (Al), copper (Cu), titanium (Ti), or the like, and may include a multi-layer or a single layer that includes the material described above.

The gate insulating layer 203 between the semiconductor layer Act and the gate electrode GE may include an inorganic insulating material, such as silicon oxide (SiOₓ), silicon nitride (SiNₓ), silicon oxynitride (SiOₓN_{y}), aluminum oxide (Al₂O₃), titanium oxide (TiOₓ), tantalum oxide (Ta₂O₅), hafnium oxide (HfO₂), or the like. The gate insulating layer 203 may be a single layer or a multi-layer that includes the above-mentioned material.

The storage capacitor Cst may include a lower electrode CE1 and an upper electrode CE2, which overlap each other with a first interlayer insulating layer 205 between the lower electrode CE1 and the upper electrode CE2. The storage capacitor Cst may overlap the thin-film transistor TFT. In this regard, FIG. 18 illustrates that the gate electrode GE of the thin-film transistor TFT is the lower electrode CE1 of the storage capacitor Cst. In another example, the storage capacitor Cst may not overlap the thin-film transistor TFT. The storage capacitor Cst may be covered by a second interlayer insulating layer 207. The upper electrode CE2 of the storage capacitor Cst may include a conductive material including Mo, Al, Cu, Ti, or the like, and may include a multi-layer or a single layer that includes the above-mentioned material.

The first interlayer insulating layer 205 and the second interlayer insulating layer 207 may each include an inorganic insulating material, such as silicon oxide (SiOₓ), silicon nitride (SiNₓ), silicon oxynitride (SiOₓN_{y}), aluminum oxide (Al₂O₃), titanium oxide (TiOₓ), tantalum oxide (Ta₂O₅), hafnium oxide (HfO₂), or the like. The first interlayer insulating layer 205 and the second interlayer insulating layer 207 may each be a single layer or a multi-layer that includes the above-mentioned material.

The source electrode SE, the drain electrode DE, and the data line DL may be disposed on the same layer, and may include the same material. For example, the source electrode SE, the drain electrode DE, and the data line DL may be disposed on the second interlayer insulating layer 207. The source electrode SE, the drain electrode DE, and the data line DL may each include a material having good conductivity. The source electrode SE and the drain electrode DE may each include a conductive material including Mo, Al, Cu, Ti, or the like, and may include a multi-layer or a single layer that includes the above-mentioned material. In an embodiment, the source electrode SE, the drain electrode DE, and the data line DL may each include a multi-layer of Ti/Al/Ti.

The first pixel circuit PC1, the second pixel circuit PC2, and the third pixel circuit PC3, each of which includes the thin-film transistor TFT and the storage capacitor Cst, may be covered with a first organic insulating layer 209. An upper surface of the first organic insulating layer 209 may be substantially flat.

The first organic light-emitting diode OLED1 electrically connected to the first pixel circuit PC1, the second organic light-emitting diode OLED2 electrically connected to the second pixel circuit PC2, and the third organic light-emitting diode OLED3 electrically connected to the third pixel circuit PC3 may be disposed on the first organic insulating layer 209.

The first pixel circuit PC1 may be electrically connected to a first pixel electrode 221r of the first organic light-emitting diode OLED1. For example, as shown in FIG. 18, a contact metal layer CM may be between the thin-film transistor TFT and the first pixel electrode 221r. The contact metal layer CM may be in contact with the thin-film transistor TFT through a contact hole penetrating the first organic insulating layer 209, and the first pixel electrode 221r may be in contact with the contact metal layer CM through a contact hole penetrating a second organic insulating layer 211 on the contact metal layer CM. The contact metal layer CM may include a conductive material including Mo, Al, Cu, Ti, or the like and may be a multilayer or a single layer including the above-mentioned material. In an embodiment, the contact metal layer CM may include a multi-layer of Ti/Al/Ti.

The first organic insulating layer 209 and the second organic insulating layer 211 may each include a general commercial polymer such as poly(methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof. In an embodiment, the first organic insulating layer 209 and the second organic insulating layer 211 may each include polyimide (PI).

According to another example, any one of the first organic insulating layer 209 and the second organic insulating layer 211 may be omitted. For example, the contact metal layer CM may be omitted.

The first organic light-emitting diode OLED1 may include the first pixel electrode 221r, a first emission layer 222r, and a first opposite electrode 223r. The second organic light-emitting diode OLED2 may include a second pixel electrode 221g, a second emission layer 222g, and a second opposite electrode 223g. The third organic light-emitting diode OLED3 may include a third pixel electrode 221b, a third emission layer 222b, and a third opposite electrode 223b. The second organic light-emitting diode OLED2 and the third organic light-emitting diode OLED3 may each have a structure similar to or the same as that of the first organic light-emitting diode OLED1.

The first pixel electrode 221r may be disposed on the second organic insulating layer 211. The first pixel electrode 221r may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another example, the first pixel electrode 221r may include a reflective film. For example, the reflective film may include silver (Ag), magnesium (Mg), Al, platinum (Pt), palladium (Pd), gold (Au), nickel (Ni), neodymium (Nd), iridium (Ir), chromium (Cr), or a compound thereof. In another example, the first pixel electrode 221r may further include a film including ITO, IZO, ZnO, or In₂O₃ above/below the reflective film mentioned above.

A pixel defining layer 213 and a bank layer 215 may be disposed on the first pixel electrode 221r. When viewed from a direction (e.g., z-axis direction) substantially perpendicular to the substrate 100, the pixel defining layer 213 may overlap an edge portion of the first pixel electrode 221r. The pixel defining layer 213 may include an inorganic insulating material such as silicon nitride (SiNₓ), silicon oxynitride (SiOₓN_{y}), or silicon oxide (SiOₓ).

A first remaining sacrificial layer 212R may be between the first pixel electrode 221r and the pixel defining layer 213. The first remaining sacrificial layer 212R may be a portion remaining after a sacrificial layer protecting an upper surface of the first pixel electrode 221r is removed. When viewed from a direction (e.g., z-axis direction) substantially perpendicular to the substrate 100, the first remaining sacrificial layer 212R may be in a region where the pixel defining layer 213 and the first pixel electrode 221r overlap each other. For example, the first remaining sacrificial layer 212R may be positioned along the edge portion of the first pixel electrode 221r to expose a central portion of the first pixel electrode 221r.

The first remaining sacrificial layer 212R may be continuously formed with the first pixel electrode 221r, and may include a material that is selectively etched without damaging the first pixel electrode 221r. For example, the first remaining sacrificial layer 212R may include indium gallium zinc oxide (IGZO) and/or indium zinc oxide (IZO).

The first remaining sacrificial layer 212R and the pixel defining layer 213 may overlap the edge portion of the first pixel electrode 221r to increase a distance between the first pixel electrode 221r and the bank layer 215 and the first opposite electrode 223r, thereby preventing an arc or the like from being generated between the first pixel electrode 221r and the first opposite electrode 223r and the first opposite electrode 223r. In some embodiments, a sacrificial layer may be completely removed so that the first remaining sacrificial layer 212R may not exist. For example, a groove formed by removing the sacrificial layer between the first pixel electrode 221r and the pixel defining layer 213 may be empty or filled with the first emission layer 222r to be described below.

The bank layer 215 may be disposed on the pixel defining layer 213. The bank layer 215 may include a conductive material. For example, the bank layer 215 may include a conductive material including Mo, Al, Cu, Ti, or the like, and may include a multi-layer or a single layer that includes the above-mentioned material. For example, the bank layer 215 may have a double-layered structure of Al/Ti or a triple-layered structure of Ti/Al/Ti.

The pixel defining layer 213 and the bank layer 215 may extend from the display area DA to the peripheral area PA (refer FIG. 16) of the substrate 100, and the bank layer 215 may be in contact with (e.g., in direct contact with) the common power supply line 16 (refer to FIG. 16) in the peripheral area PA (refer FIG. 16) through an opening portion of the pixel defining layer 213. Accordingly, the bank layer 215 may function as a connection electrode or an auxiliary line for transferring the common voltage ELVSS to the first opposite electrode 223r, the second opposite electrode 223g, and the third opposite electrode 223b to be described below.

A first conductive layer 217 may be disposed on the bank layer 215. The first conductive layer 217 may have a tip portion 217T protruding outward with respect to a center portion of the first pixel electrode 221r. When viewed from a direction (e.g., z-axis direction) perpendicular to an upper surface of the substrate 100, the tip portion 217T of the first conductive layer 217 may have a loop shape surrounding (e.g., completely surrounding) the first pixel electrode 221r.

A first opening OP1 may expose a central portion of an upper surface of the first pixel electrode 221r by penetrating the pixel defining layer 213, the bank layer 215, and the first conductive layer 217, and the first emission layer 222r to be described below may overlap and contact the first pixel electrode 221r through the first opening OP1. Accordingly, the first opening OP1 may define a first emission area EA1. An outside of the first emission area EA1 may be defined as a non-emission area NEA. Further, a second opening OP2 may define a second emission area EA2, and a third opening OP3 may define a third emission area EA3.

A portion of the first conductive layer 217 may be spaced apart from the bank layer 215 in a direction (e.g., z-axis direction) perpendicular to the substrate 100 to have the tip portion 217T protruding outward with respect to the center portion of the first pixel electrode 221r. Because the tip portion 217T of the first conductive layer 217 is formed by removing a portion of the sacrificial layer between the first conductive layer 217 and the bank layer 215, the first conductive layer 217 may have an undercut structure/shape. Accordingly, the tip portion 217T of the first conductive layer 217 may form an eaves structure in which a lower surface thereof is exposed. A protruding length of the tip portion 217T of the first conductive layer 217 may be about 0.5 μm or more. In some embodiments, the protruding length of the tip portion 217T of the first conductive layer 217 may be about 0.3 μm to about 1 μm or about 0.3 m to about 0.7 m.

The first conductive layer 217 may include a conductive material. For example, the first conductive layer 217 may include a conductive material including Mo, Al, Cu, Ti, or the like, and may include a multi-layer or a single layer that includes the above-mentioned material. For example, the first conductive layer 217 may have a double-layered structure of Al/Ti or a triple-layered structure of Ti/Al/Ti.

In an embodiment, a low-reflection layer may be disposed on the first conductive layer 217. The low-reflection layer may be a layer having a lower surface reflectance than that of the first conductive layer 217. The low-reflection layer may prevent light (e.g., external light) incident toward the display device 2 from being reflected from a surface of the first conductive layer 217 to be recognized by a user of the display device 2.

In an embodiment, the low-reflection layer may include a low-reflection material. The low-reflection material may include a metal oxide having a high light absorption rate, e.g., a high extinction coefficient (k). For example, the low-reflection layer may include at least one of copper oxide (CuO), calcium oxide (CaO), molybdenum oxide (MoOx), and zinc oxide (ZnO). In some embodiments, the low-reflection layer may include a material obtained by mixing copper oxide (CuO) and calcium oxide (CaO).

A second remaining sacrificial layer 214R may be between the first conductive layer 217 and the bank layer 215. The second remaining sacrificial layer 214R may be a remaining portion of the sacrificial layer removed to form the tip portion 217T of the first conductive layer 217. When viewed from a direction (e.g., z-axis direction) substantially perpendicular to the substrate 100, the second remaining sacrificial layer 214R may be spaced apart from the first pixel electrode 221r by a certain distance, and may have a shape surrounding (e.g., completely surrounding) the first pixel electrode 221r. Due to the second remaining sacrificial layer 214R, the first conductive layer 217 may have an undercut structure/shape.

The second remaining sacrificial layer 214R may determine the protruding length of the tip portion 217T of the first conductive layer 217. For example, the second remaining sacrificial layer 214R may be positioned inside an end portion of the tip portion 217T of the first conductive layer 217, and the protruding length of the tip portion 217T may be a length from a sidewall of the second remaining sacrificial layer 214R to the end portion of the tip portion 217T.

The second remaining sacrificial layer 214R may include a material that is selectively etched without damaging the first pixel electrode 221r, the bank layer 215, and the first conductive layer 217. For example, the second remaining sacrificial layer 214R and the first remaining sacrificial layer 212R may include the same material. The second remaining sacrificial layer 214R may include indium gallium zinc oxide (IGZO) and/or indium zinc oxide (IZO).

The first emission layer 222r may be positioned over the first pixel electrode 221r and the first conductive layer 217. For example, the first emission layer 222r may be arranged to be in contact with the first pixel electrode 221r through the first opening OP1. The first pixel electrode 221r may include a polymer organic material or a low-molecular-weight organic material, which emits light of the first color (e.g., red). In another example, the first emission layer 222r may include an inorganic material or quantum dots.

The first emission layer 222r may include a first functional layer and a second functional layer thereabove and/or therebelow. The first functional layer may include a hole transport layer (HTL) and/or a hole injection layer (HIL). The second functional layer may include an electron transport layer (ETL) and/or an electron injection layer (EIL).

FIG. 18 shows a single-stacked structure including a single emission layer, but in another example, the display device 2 may also have a tandem structure, that is a multi-stacked structure including a plurality of emission layers. In case that the display device 2 has a tandem structure, a charge generation layer (CGL) may be arranged between adjacent stacks of the multi-stacked structure.

The first emission layer 222r may be disconnected from a dummy portion 222rp by the tip portion 217T of the first conductive layer 217. For example, the first emission layer 222r may include the same material and/or the same number of sub-layers (e.g., the first functional layer, the second functional layer, or the like) as that of the dummy portion 222rp.

The first emission layer 222r may have at least one first hole 222rh exposing a portion of an upper surface of the first conductive layer 217.

The second emission layer 222g may include a polymer organic material or a low-molecular-weight organic material, which emits light of the second color (e.g., green), and the third emission layer 222b may include a polymer organic material or a low-molecular-weight organic material, which emits light of the third color (e.g., blue).

The first opposite electrode 223r may be disconnected from a dummy portion 223rp by the tip portion 217T of the first conductive layer 217. The first opposite electrode 223r and the dummy portion 223rp may include the same material.

The first opposite electrode 223r may include a transparent layer or a semi-transparent layer. The transparent layer or the semi-transparent layer may include Ag, Mg, Al, Pt, Pd, Au, Ni, Nd, Ir, Cr, lithium (Li), calcium (Ca), alloys thereof, or the like. In another example, the first opposite electrode 223r may further include a layer, such as ITO, IZO, ZnO, or In₂O₃, above the transparent layer or the semi-transparent layer including the materials described above.

A first inorganic encapsulation layer 311 may be disposed on the first opposite electrode 223r. Because the first inorganic encapsulation layer 311 has a relatively excellent step coverage, the first inorganic encapsulation layer 311 may cover at least a portion of an exposed lower surface of the tip portion 217T of the first conductive layer 217. For example, the first inorganic encapsulation layer 311 may be continuously formed to cover upper and side surfaces of the first opposite electrode 223r, a side surface of the first emission layer 222r, side and lower surfaces of the tip portion 217T of the first conductive layer 217, a side surface of the second remaining sacrificial layer 214R, and an upper surface of the bank layer 215.

The first inorganic encapsulation layer 311 may include an inorganic insulating material such as silicon nitride (SiNₓ), silicon oxynitride (SiOₓN_{y}), and silicon oxide (SiOₓ). The first inorganic encapsulation layer 311 may be in contact with (e.g., in direct contact with) a metal surface at the side and lower surfaces of the tip portion 217T of the first conductive layer 217 to form an inorganic contact region ICR. Accordingly, the inorganic contact region ICR may form a closed loop surrounding (e.g., completely surrounding) the first organic light-emitting diode OLED1 to minimize (or block) a path through which impurities, such as moisture and/or air, penetrate.

As shown in FIG. 18, a second inorganic encapsulation layer 312 may seal the second organic light-emitting diode OLED2, and a third inorganic encapsulation layer 313 may seal the third organic light-emitting diode OLED3. As the first inorganic encapsulation layer 311, the second inorganic encapsulation layer 312, and the third inorganic encapsulation layer 313 form the inorganic contact region ICR in the display area DA, an inorganic contact region of the peripheral area PA (refer to FIG. 16) required to reduce the peeling defect due to emission layer may be reduced. For example, as an organic light-emitting diode is sealed in units of pixels, although a path through which impurities, such as moisture and/or air, penetrate occurs at one pixel or at the boundary of the substrate 100, a resulting defect may be prevented from being propagated to neighboring pixels.

An organic planarization layer 410 may be arranged to cover the first inorganic encapsulation layer 311, the second inorganic encapsulation layer 312, and the third inorganic encapsulation layer 313. The organic planarization layer 410 may cover irregularities caused by the pixel defining layer 213, the bank layer 215, and the first conductive layer 217 to provide a flat base surface for components disposed on an upper portion of the organic planarization layer 410. The organic planarization layer 410 may include a polymer-based material. The polymer-based material may include an acrylic resin, an epoxy resin, polyimide, polyethylene, or the like.

In an embodiment, a refractive index of the organic planarization layer 410 may be greater than a refractive index of each of the first inorganic encapsulation layer 311, the second inorganic encapsulation layer 312, and the third inorganic encapsulation layer 313. For example, the refractive index of the organic planarization layer 410 may be about 1.6 or more. The refractive index of the organic planarization layer 410 may be about 1.6 to about 1.9. The organic planarization layer 410 may further include dispersed particles for high refractive index. For example, metal oxide particles, such as zinc oxide (ZnOₓ), titanium oxide (TiO₂), zirconium oxide (ZrO₂), barium titanate (BaTiO₃), or the like, may be dispersed in the organic planarization layer 410.

A protective layer 420 may be disposed on the organic planarization layer 410. The protective layer 420 may include an inorganic insulating material such as silicon nitride (SiNₓ), silicon oxynitride (SiOₓN_{y}), and silicon oxide (SiOₓ). In an embodiment, a refractive index of the protective layer 420 may be less than the refractive index of the organic planarization layer 410.

An anti-reflection layer 500 including a first color filter 510, a second color filter 520, a third color filter 530, a light-blocking layer 540, and an overcoat layer 550 may be disposed on the protective layer 420. The anti-reflection layer 500 may reduce the reflectance of light (e.g., external light) incident from the outside toward the display device 2.

The light-blocking layer 540 may overlap the bank layer 215 and the first conductive layer 217 to at least partially absorb light reflected by the bank layer 215 and the first conductive layer 217 in a non-emission area NEA. For example, the non-emission area NEA may be defined as an area that does not overlap the first emission area EA1, the second emission area EA2, and the third emission area EA3. The light-blocking layer 540 may include black pigment. The light-blocking layer 540 may be a black matrix. The light-blocking layer 540 may include a first filter opening 540OP1 corresponding to the first emission area EA1, a second filter opening 540OP2 corresponding to the second emission area EA2, and a third filter opening 540OP3 corresponding to the third emission area EA3.

The first color filter 510 may be positioned in the first filter opening 540OP1 to correspond to the first emission layer 222r disposed therebelow. The first color filter 510 may selectively transmit light emitted by the first emission layer 222r. For example, the first color filter 510 as shown in FIG. 18 may be a red color filter that selectively transmits red light.

For example, the second color filter 520 may be positioned in the second filter opening 540OP2 to correspond to the second emission layer 222g. The second color filter 520 may selectively transmit light emitted by the second emission layer 222g. The third color filter 530 may be positioned in the third filter opening 540OP3 to correspond to the third emission layer 222b. The third color filter 530 may selectively transmit light emitted by the third emission layer 222b. For example, the second color filter 520 as shown in FIG. 18 may be a green color filter that selectively transmits green light, and the third color filter 530 may be a blue color filter that selectively transmits blue light.

The overcoat layer 550 may be disposed on the first to third color filters 510, 520, and 530. The overcoat layer 550 may be a transparent layer, which covers irregularities caused by the first to third color filters 510, 520, and 530 and the light-blocking layer 540 and provide a flat upper surface. The overcoat layer 550 may include a colorless transparent organic material, such as an acrylic resin.

According to embodiments, durability and manufacturing efficiency of an apparatus for manufacturing a display device may be improved.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display device, the apparatus comprising:
a chamber;
a mask assembly disposed inside the chamber to face a display substrate; and
a deposition source unit that is disposed inside the chamber to face the mask assembly, supplies a deposition material, and deposits the deposition material on the display substrate by passing through the mask assembly, wherein
the mask assembly comprises:
a first mask layer comprising a first mask opening; and
a second mask layer disposed on the first mask layer and comprising a second mask opening overlapping the first mask opening, and
the second mask layer comprises:
a first inorganic layer;
a first organic layer disposed on the first inorganic layer; and
a second inorganic layer disposed on the first organic layer.

2. The apparatus of claim 1, wherein the second mask opening comprises:
a first inorganic opening disposed in the first inorganic layer;
a first organic opening disposed in the first organic layer; and
a second inorganic opening disposed in the second inorganic layer.

3. The apparatus of claim 2, wherein a width of the first organic opening is greater than a width of the second inorganic opening in a cross-sectional view.

4. The apparatus of claim 3, wherein a width of the first inorganic opening and the width of the second inorganic opening are same as each other in a cross-sectional view.

5. The apparatus of claim 2, wherein a width of the first inorganic opening, a width of the first organic opening, and a width of the second inorganic opening are same as each other in a cross-sectional view.

6. The apparatus of claim 1, wherein a thickness of the first organic layer is greater than a thickness of the first inorganic layer and a thickness of the second inorganic layer in a cross-sectional view.

7. The apparatus of claim 1, wherein the first mask layer comprises a silicon material.

8. The apparatus of claim 1, wherein the second mask layer further comprises:
a second organic layer disposed on the second inorganic layer; and
a third inorganic layer disposed on the second organic layer.

9. A method of manufacturing a display device, the method comprising:
disposing a display substrate inside a chamber;
disposing a mask assembly inside the chamber; and
supplying a deposition material toward the mask assembly from a deposition source unit, wherein
the disposing of the mask assembly comprises:
disposing a second mask layer on a first mask layer;
forming a first mask opening in the first mask layer; and
forming a second mask opening in the second mask layer,
the disposing of the second mask layer comprises:
disposing a first inorganic layer on the first mask layer;
disposing a first organic layer on the first inorganic layer; and
disposing a second inorganic layer on the first organic layer.

10. The method of claim 9, wherein the forming of the second mask opening comprises:
forming a first inorganic opening in the first inorganic layer;
forming a first organic opening in the first organic layer; and
forming a second inorganic opening in the second inorganic layer.

11. The method of claim 10, wherein the forming of the second inorganic opening comprises:
disposing, on the second inorganic layer, a first photoresist layer in which a first photo-opening is disposed;
etching a portion of the second inorganic layer that overlaps the first photo-opening; and
removing the first photoresist layer.

12. The method of claim 11, wherein the forming of the first organic opening comprises etching a portion of the first organic layer that overlaps the second inorganic opening.

13. The method of claim 12, wherein a width of the first organic opening is greater than a width of the second inorganic opening in a cross-sectional view.

14. The method of claim 10, wherein the forming of the first inorganic opening comprises etching a portion of the first inorganic layer that overlaps the second inorganic opening.

15. The method of claim 14, wherein a width of the first inorganic opening and a width of the second inorganic opening are same as each other in a cross-sectional view.

16. A mask assembly comprising:
a first mask layer comprising a first mask opening; and
a second mask layer disposed on the first mask layer and comprising a second mask opening overlapping the first mask opening, wherein
the second mask layer comprises:
a first inorganic layer;
a first organic layer disposed on the first inorganic layer; and
a second inorganic layer disposed on the first organic layer.

17. The mask assembly of claim 16, wherein the second mask opening comprises:
a first inorganic opening disposed in the first inorganic layer;
a first organic opening disposed in the first organic layer; and
a second inorganic opening disposed in the second inorganic layer.

18. The mask assembly of claim 17, wherein a width of the first organic opening is greater than a width of the second inorganic opening in a cross-sectional view.

19. The mask assembly of claim 16, wherein a thickness of the first organic layer is greater than a thickness of the first inorganic layer and a thickness of the second inorganic layer in a cross-sectional view.

20. The mask assembly of claim 16, wherein the first mask layer comprises a silicon material.
